(19) United States
(12) Patent Application Publication
(10) Pub. No.: US 2026/0052788 A1
(43) Pub. Date: Feb. 19, 2026

(54) IMAGE SENSOR AND METHOD OF MANUFACTURING THE SAME

(71) Applicant: Samsung Electronics Co., Ltd., Suwon-si (KR)

(72) Inventors: Jinhyung Kim, Suwon-si (KR); CHANHYUNG KIM, Suwon-si (KR); INYONG PARK, Suwon-si (KR)

(21) Appl. No.: 19/290,121

(22) Filed: Aug. 4, 2025

(30) Foreign Application Priority Data
Aug. 14, 2024 (KR) 10-2024-0109071

(51) Int. Cl. H10F 39/00; H04N 25/13; H04N 25/778; H10F 39/18

(52) U.S. Cl. CPC H10F 39/8057; H04N 25/134; H04N 25/778; H10F 39/024; H10F 39/182; H10F 39/8053; H10F 39/8063; H10F 39/807

(57) ABSTRACT

The present application relates to an image sensor including a substrate having a first surface and a second surface opposite to the first surface and including pixel regions spaced apart from each other, a light transmitting layer covering the second surface, and including an anti-reflection portion having an opening, a light shielding portion provided in the light transmitting layer, filling the opening, and covering a portion of a first pixel region of the pixel regions, a grid disposed on the light transmitting layer, color filters filling openings of the grid, and microlenses disposed on the color filters.

### CROSS-REFERENCE TO RELATED APPLICATION(S)

This U.S. non-provisional application claims priority under 35 USC § 119 to Korean Patent Application No. 10-2024-0109071, filed on Aug. 14, 2024, in the Korean Intellectual Property Office, the disclosure of which is herein incorporated by reference in its entirety.

### BACKGROUND

The present application relates to an image sensor and method of manufacturing the same.

An image sensor is a semiconductor element that converts an optical image into an electrical signal. Recently, with the development of the computer and communication industries, the demand for image sensors with improved performance has increased in various fields such as digital cameras, camcorders, Personal Communication System (PCS), gaming devices, security cameras, and medical micro cameras. The Image sensors can be classified into charge coupled device (CCD) type and complementary metal oxide semiconductor (CMOS) type. The CMOS type image sensor is provided with a plurality of pixels arranged two-dimensionally. Each of the pixels includes a photodiode (PD). The photodiode serves to convert incident light into an electrical signal.

### SUMMARY

The present application is directed to providing an image sensor including a light shielding pattern inserted into a light transmitting film and a method of manufacturing the same.

The present application relates to an image sensor including a substrate having a first surface and a second surface opposite to the first surface and including pixel regions spaced apart from each other, a light transmitting layer covering the second surface, and including an anti-reflection portion having an opening, a light shielding portion provided in the light transmitting layer, filling the opening, and covering a portion a first pixel region of the pixel regions, a grid disposed on the light transmitting layer, color filters filling openings of the grid, and microlenses disposed on the color filters.

The first pixel region covered by the light shielding portion may include at least one an autofocusing pixel.

Each of the pixel regions may include a pair of sub-pixel regions spaced apart from each other and a pair of photodiodes provided in the pair of sub-pixel regions, respectively, and the light shielding portion may cover one of the pair of sub-pixel regions.

The image sensor may further include a single photodiode provided in each of the pixel regions, wherein the light shielding portion may cover a portion of the single photodiode of the first pixel region.

The light transmitting layer may further include a surface insulating film disposed between the second surface and the light shielding portion and between the second surface and the anti-reflection portion.

The light transmitting layer may further include a capping film covering the light shielding portion and the anti-reflection portion.

The light transmitting layer may be above the second surface. The light shielding portion may be provided at the same height as the light transmitting layer. The light shielding portion may be above the portion of the first pixel region. The grid may be above the light transmitting layer. The microlenses may be above the color filters.

The light shielding portion may have a lower portion protruding lower than a bottom surface of the anti-reflection portion, the light transmitting layer further includes a surface insulating film disposed between the anti-reflection portion and the second surface, and the surface insulating film surrounds at least a side surface of the lower portion of the light shielding portion.

The light transmitting layer may further include a capping film provided on the anti-reflection portion, the light shielding portion may have an upper portion protruding higher than a top surface of the anti-reflection portion, and a side surface of the upper portion of the light shielding portion may be surrounded by the capping film.

A thickness of the light shielding portion may differ from a thickness of the anti-reflection portion.

The light shielding portion may be made of a material that reflects, blocks, and/or absorbs light.

The light shielding portion may be made of at least one of aluminum, titanium, a titanium nitride, tungsten, tantalum, a tantalum nitride, an aluminum oxide, a tantalum oxide, copper, molybdenum, nickel, a red organic material, a green organic material, a blue organic material, a cyan organic material, a magenta organic material, a yellow organic material, a black organic material, or a gray organic material.

The anti-reflection portion may include one or more of: an oxide containing silicon or hafnium; a nitride containing silicon or hafnium; a film that reduces reflection; or a material with a low reflectance.

The light transmitting layer may allow over 90% of incident light to be transmitted.

The image sensor may further include a transfer gate disposed on the first surface of the substrate and provided on each of the pixel regions, and a floating diffusion region provided in each of the pixel regions at one side of the transfer gate and adjacent to the first surface.

The present application relates to an image sensor including a substrate having a first surface and a second surface opposite to the first surface, a first deep element isolation pattern disposed in the substrate to correspond to pixel regions, each of which includes a pair of sub-pixel regions, a second deep element isolation pattern disposed between a respective pair of sub-pixel regions, an anti-reflection portion covering the second surface and having an opening, a light shielding portion filling the opening, a grid disposed on the anti-reflection portion, color filters filling openings of the grid, and microlenses disposed on the color filters, wherein at least a first pixel region of the pixel regions is part of an autofocusing pixel, and the light shielding portion covers at least a portion of one of the pair of sub-pixel regions of the first pixel region.

The image sensor may further include a surface insulating film disposed between the second surface and the light shielding portion and between the second surface and the anti-reflection portion.

The image sensor may further include a capping film covering the light shielding portion and the anti-reflection portion, wherein the grid may be provided on the capping film.

A thickness of the light shielding portion may differ from a thickness of the anti-reflection portion.

The light shielding portion may be made of a material that reflects, blocks, and/or absorbs light.

The present application relates to a method of manufacturing an image sensor, including forming a surface insulating film on one surface of a substrate, forming an anti-reflection film on the surface insulating film, etching the anti-reflection film to form an opening in the anti-reflection film, forming a light shielding portion in the opening, forming a capping film on the light shielding portion and the anti-reflection film, and forming a grid and a color filter on the capping film.

The forming the light shielding portion may include forming a light shielding film filling the opening on the anti-reflection film, and planarizing the light shielding film to form the light shielding portion, and wherein when the light shielding film is planarized, the light shielding film may be over-etched so that a top surface of the light shielding portion is lower than a top surface of the anti-reflection film.

The forming the light shielding portion may include forming a light shielding film filling the opening on the anti-reflection film, planarizing the light shielding film until the anti-reflection film is exposed to form the light shielding portion, and etching the exposed anti-reflection film, wherein a top surface of the etched anti-reflection film may be lower than a top surface of the light shielding portion.

### BRIEF DESCRIPTION OF DRAWINGS

FIG. 1 is a block diagram of an image sensor according to one embodiment of the present application.

FIG. 2 is a circuit diagram of a pixel array of the image sensor of the present application.

FIGS. 3A and 3B are circuit diagrams of pixel groups of image sensors according to some embodiments of the present application.

FIG. 4 is a cross-sectional view of an image sensor according to one embodiment of the present application.

FIG. 5 is an enlarged cross-sectional view of portion ‘A’ of FIG. 4.

FIGS. 6 and 7 show image sensors according to some embodiments of the present application, which are enlarged cross-sectional views corresponding to portion ‘A’ of FIG. 4.

FIGS. 8 to 10 show image sensors according to some embodiments of the present application, which are enlarged cross-sectional views corresponding to portion ‘A’ of FIG. 4.

FIGS. 11 to 13 show image sensors according to some embodiments of the present application, which are enlarged cross-sectional views corresponding to portion ‘A’ of FIG. 4.

FIG. 14 shows an image sensor according to one embodiment of the present application, which is an enlarged cross-sectional view corresponding to portion ‘A’ of FIG. 4.

FIGS. 15 to 19 are cross-sectional views showing a method of manufacturing the image sensor according to one embodiment of the present application.

FIG. 20 shows an image sensor according to one embodiment of the present application, which is an enlarged cross-sectional view corresponding to portion ‘A’ of FIG. 4.

FIG. 21 is a cross-sectional view of an image sensor according to one embodiment of the present application.

FIG. 22 is a cross-sectional view of an image sensor according to one embodiment of the present application.

### DETAILED DESCRIPTION

Hereinafter, embodiments of the present application are described in detail with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second”in the specification or another claim).

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Items described in the singular herein may be provided in plural, as can be seen, for example, in the drawings. Thus, the description of a single item that is provided in plural should be understood to be applicable to the remaining plurality of items unless context indicates otherwise.

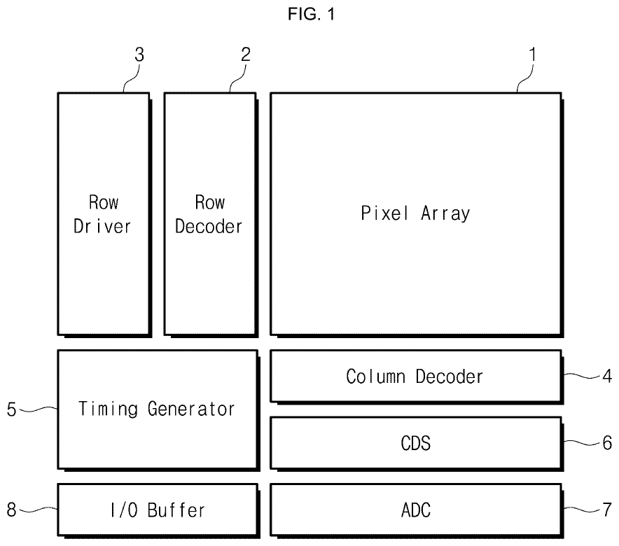

FIG. 1 is a block diagram of an image sensor according to one embodiment of the present application.

Referring to FIG. 1, the image sensor according to some embodiments of the present application may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

The pixel array 1 may include a plurality of pixels arranged two-dimensionally, and the pixels may convert optical signals into electrical signals. A pixel, or unit pixel may refer herein to a sensor element (e.g., a single-pixel sensor) of the disclosed image sensor, and/or may refer to a smallest addressable light-sensing element of the image sensor. In some cases, a pixel may be included as part of a pixel array or pixel group, and/or within a pixel region, as described herein. In some cases, a pixel may include one or more sub-pixels, as described herein, and thus is not limited to a single unit pixel. The pixel array 1 may be driven by a plurality of driving signals (e.g., a pixel selection signal, a reset signal, and/or a charge transfer signal) transmitted from the row driver 3. The converted electrical signals may be provided to the correlated double sampler 6.

The row driver 3 may provide the plurality of driving signals to the pixel array 1 for driving the plurality of pixels based on decoded results from the row decoder 2. When the pixels are arranged in a matrix form, the driving signals may be provided in a row unit.

The timing generator 5 may provide a timing signal and a control signal to the row decoder 2 and the column decoder 4.

The correlated double sampler 6 may receive the electrical signals generated from the pixel array 1 and may hold and sample the received signals. The correlated double sampler 6 may double sample a specific noise level and a signal level caused by an electrical signal to output a difference level corresponding to the difference between the noise level and the signal level.

The analog to digital converter 7 may convert an analog signal corresponding to the difference level output from the correlated double sampler 6 into a digital signal and may output the digital signal.

The input/output buffer 8 may latch the digital signals and sequentially output the latched signals to an image signal processor (not shown) based on the decoded results from the column decoder 4.

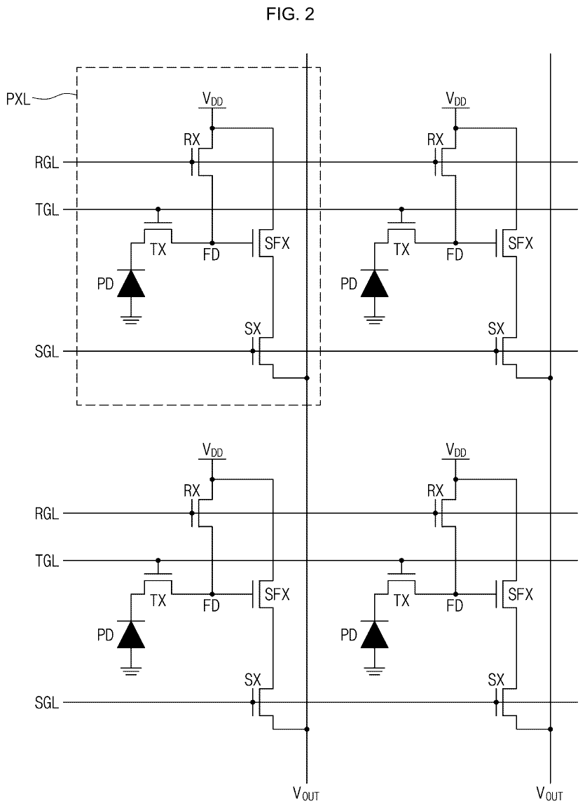

FIG. 2 is a circuit diagram of the pixels included in the pixel array of the image sensor according to one embodiment of the present application.

Referring to FIG. 2, a pixel array may include a plurality of pixels PXL, and the pixels PXL may be arranged in a matrix form. Each of the pixels PXL may include a transfer transistor TX and logic transistors RX, SX, and SFX. The logic transistors RX, SX, and SFX may include a reset transistor RX, a selection transistor SX, and a source follower transistor SFX. In addition, each of the pixels PXL may include a photodiode PD and a floating diffusion region FD.

The photodiode PD may generate and accumulate photocharges in proportion to the amount of light incident from the outside. The photodiode PD may include a photoelectric conversion element, a phototransistor, a photogate, a pinned photodiode, or a combination thereof. The transfer transistor TX may transfer the photocharges generated from the photodiode PD to the floating diffusion region FD. A transfer gate of the transfer transistor TX may be connected to a transfer gate line TGL. The floating diffusion region FD may receive and cumulatively store the photocharges generated from the photodiode PD.

A gate of the source follower transistor SFX may be connected to the floating diffusion region FD. A drain terminal of the source follower transistor SFX may be connected to a power terminal VDD that may receive a power voltage. The source follower transistor SFX may be controlled according to the amount of photocharges accumulated in the floating diffusion region FD.

The reset transistor RX may periodically reset the charges accumulated in the floating diffusion region FD. A gate of the reset transistor RX may be connected to a reset gate line rGL. A source terminal of the reset transistor RX may be connected to the floating diffusion region FD, and a drain terminal of the reset transistor RX may be connected to the power terminal VDD. When the reset transistor RX is turned on, the power voltage of the power terminal VDD may be applied to the floating diffusion region FD through the reset transistor RX. For example, when the reset transistor RX is turned on, the charges accumulated in the floating diffusion region FD may be discharged by the power voltage, thereby resetting the floating diffusion region FD.

The source follower transistor SFX may serve as a source follower buffer amplifier. The source follower transistor SFX may amplify a potential change in the floating diffusion region FD and output the amplified potential change to an output line VOUT.

A gate of the selection transistor SX may be connected to a selection gate line SGL. A drain terminal of the selection transistor SX may be connected to the source terminal of the source follower transistor DX, and a source terminal of the selection transistor SX may be connected to the output line VOUT. The selection transistors SX of the pixels PXL to be read out in row units may be selected by a selection signal applied through a corresponding selection gate line SGL. When the selection transistor SX is turned on, the potential change amplified by the source follower transistor SFX may be output to the output line VOUT through the selection transistor SX.

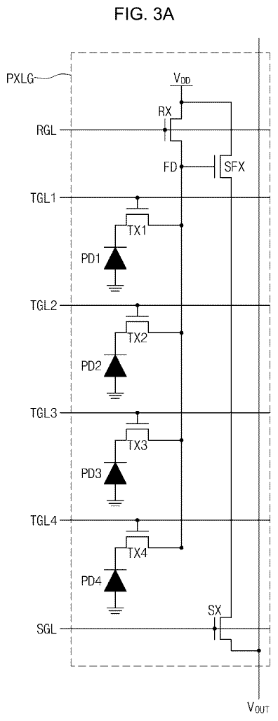

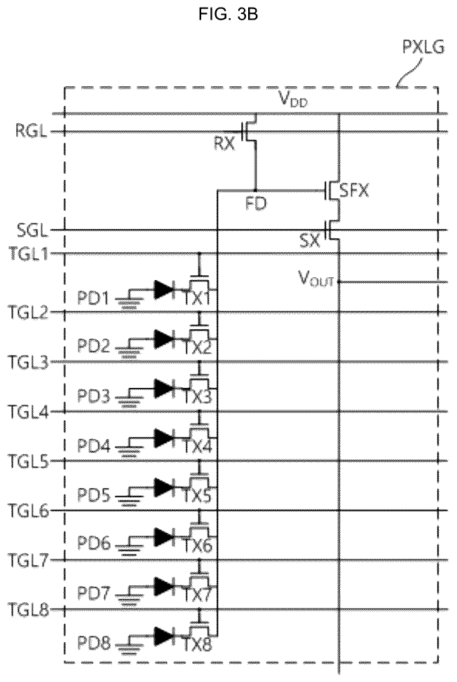

Each of the pixels PXL may include a photodiode PD, transfer transistor TX, and each of logic transistors RX, SX, and SFX as shown in FIG. 2, but the embodiments of the present application are not limited thereto. In some embodiments, some pixels adjacent to each other may configure a pixel group, and the pixels of the pixel group may share at least one of the logic transistors RX, SX, SFX. Examples related thereto will be described with reference to FIGS. 3A and 3B.

FIGS. 3A and 3B are circuit diagrams of pixel groups of image sensors according to some embodiments of the present application. Unlike individual pixels (for example, in FIG. 2), in these examples, the pixels of a pixel group may share the previously disclosed reset transistor RX, source follower transistor SFX, and selection transistor SX.

Referring to FIGS. 3A and 3B, the pixel array may include pixel groups PXLG, and each of the pixel groups PXLG may include a plurality of pixels. A circuit diagram of a single pixel group PXLG is shown in each of FIGS. 3A and 3B.

Referring to FIG. 3A, in one embodiment, the pixel group PXLG may include four pixels (for example, first to fourth pixels). The first pixel may include a first transfer transistor TX1 and a first photodiode PD1, the second pixel may include a second transfer transistor TX2 and a second photodiode PD2, the third pixel may include a third transfer transistor TX3 and a third photodiode PD3, and the fourth pixel may include a fourth transfer transistor TX4 and a fourth photodiode PD4. Gates of the first to fourth transfer transistors TX1 to TX4 may be connected to first to fourth transfer gate lines TGL1 to TGL4 respectively. In one embodiment, first to fourth pixels of the pixel group PXLG may share the previously disclosed reset transistor RX, source follower transistor SFX, and selection transistor SX.

Referring to FIG. 3B, in one embodiment, the pixel group PXLG may include four pixels, and each of the four pixels may include two sub-pixels. Thus, in this example, the pixel group PXLG may include first to eighth sub-pixels. The first to eighth sub-pixels may include first to eighth transfer transistors TX1 to TX8 and first to eighth photodiodes PD1 to PD8, respectively. Gates of the first to eighth transfer transistors TX1 to TX8 may be connected to first to eighth transfer gate lines TGL1 to TGL8, respectively. In one embodiment, the first to eighth sub-pixels may share the previously disclosed reset transistor RX, source follower transistor SFX, and selection transistor SX.

In the embodiments of FIGS. 3A and 3B, the pixel group PXLG may respectively include four pixels or eight sub-pixels. However, the embodiments of the present application are not limited thereto, and the number of pixels and/or sub-pixels in the pixel group PXLG may vary.

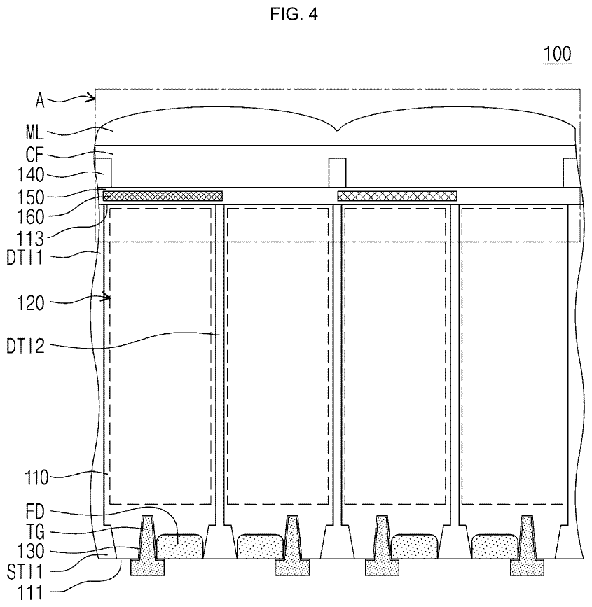

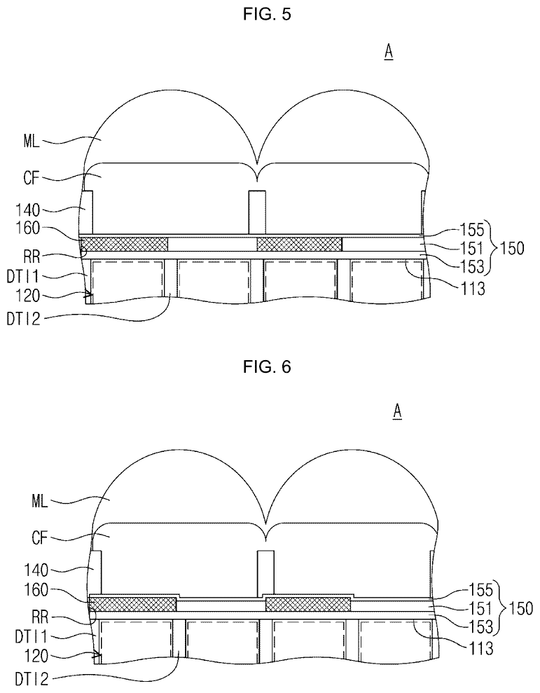

FIG. 4 is a cross-sectional view of an image sensor according to one embodiment of the present application. FIG. 5 is an enlarged cross-sectional view of portion ‘A’ of FIG. 4.

Referring to FIG. 4, an image sensor according to one embodiment may include a photoelectric conversion structure (also referred to herein as a photoelectric conversion array or a photoelectric converter) 100. The photoelectric conversion structure 100 may include a first substrate 110, a photodiode 120, a first deep element isolation pattern DTI1, a second deep element isolation pattern DTI2, a first shallow element isolation pattern STI1, a floating diffusion region FD, a transfer gate TG, a first gate insulating film 130, a grid 140, a light transmitting film 150, a light shielding pattern 160, a color filter CF, and a microlens ML.

The first substrate 110 may have a first surface 111 and a second surface 113 opposite to the first surface 111. The first surface 111 may be a front surface of the first substrate 110, and the second surface 113 may be a back surface of the first substrate 110. Light may be incident on the second surface 113 of the first substrate 110. For example, the second surface 113 of the first substrate 110 may be a light incident surface.

The first substrate 110 may be a silicon (Si) substrate, a germanium (Ge) substrate, a silicon-germanium (Si-Ge) substrate, a group II-VI compound semiconductor substrate, a group III-V compound semiconductor substrate, or a silicon on insulator (SOI) substrate. The first substrate 110 may include impurities of a first conductivity type, and accordingly, the first substrate 110 may have the first conductivity type. For example, the impurities of the first conductivity type may be a group III element. For example, the impurities of the first conductivity type may include P-type impurities such as aluminum (Al), boron (B), indium (In), and/or gallium (Ga).

The photodiode 120 may be provided in the first substrate 110. The photodiode 120 may include impurities having a second conductivity type different from the first conductivity type, and accordingly, the photodiode 120 may have the second conductivity type. For example, the impurities of the second conductivity type may be a group V element. For example, the impurities of the second conductivity type may include N-type impurities such as phosphorus, arsenic, bismuth, and/or antimony.

The first substrate 110 and the photodiode 120 may configure the above-described photodiode PD by forming a P-N junction with each other.

In one embodiment, the first deep element isolation pattern DTI1 may be provided in the first substrate 110 to define pixel regions in the first substrate 110, and at least one photodiode 120 may be provided in each of the pixel regions.

The first deep element isolation pattern DTI1 may pass through the first substrate 110. For example, the first deep element isolation pattern DTI1 may pass through the first and second surfaces 111 and 113 of the first substrate 110 and a body of the substrate between the first and second surfaces 111 and 113 of the first substrate 110.

The first deep element isolation pattern DTI1 may be formed in the first substrate 110 to surround each of the pixel regions from a planar perspective. For example, the first deep element isolation pattern DTI1 may be formed by a technique of filling a deep trench, formed by being patterned in the first substrate 110, with an insulating material, for example, by a deep trench isolation (DTI) technique. In one embodiment, the pixel region may be a portion of the first substrate 110 surrounded by the first deep element isolation pattern DTI1.

In one embodiment, the first deep element isolation pattern DTI1 may include a conductive isolation film provided in the deep trench and an insulating liner provided between the first substrate 110 and the conductive isolation film. The conductive isolation film may include a conductive material such as a doped semiconductor material (e.g., doped polysilicon). The conductive isolation film may be spaced apart from the first substrate 110 by the insulating liner, so that the conductive isolation film may be electrically isolated from the first substrate 110 when the image sensor operates.

In one embodiment, each of the pixel regions may include a pair of sub-pixel regions. In this case, the photodiode 120 may be disposed in each of the pair of sub-pixel regions. For example, a pair of photodiodes 120 may be disposed in the pair of sub-pixel regions, respectively. When each of the pixel regions includes a pair of sub-pixel regions, each of the pixel regions may correspond to one of the pixels of pixel group PXLG in FIG. 3B, which pixel in turn includes two sub-pixels. For example, each of the sub-pixels of the pixels in the pixel group PXLG of FIG. 3B may be formed on and in each of the pixel regions.

The pair of sub-pixel regions may be separated by at least one of various isolation techniques. For example, the pair of sub-pixel regions may be separated from each other by a doping isolation technique. For example, a doped isolation region may be provided between the pair of sub-pixel regions. Alternatively, the pair of sub-pixel regions may be separated from each other by the doped isolation region and at least one deep element isolation pattern. For example, the doped isolation region and at least one deep element isolation pattern may be provided between the pair of sub-pixel regions. Alternatively, only at least one deep element isolation pattern may be provided between the pair of sub-pixel regions (e.g., without the doped isolation region).

In one embodiment, each of the pixel regions may include the pair of sub-pixel regions, and the second deep element isolation pattern DTI2 may be provided between the pair of sub-pixel regions.

The above-described embodiment discloses that each of the pixel regions includes the pair of sub-pixel regions, but the embodiments of the present application are not limited thereto. In one embodiment, each of the pixel regions may not include the sub-pixel regions. In this case, each of the pixels PXL in FIG. 2 may be formed on and in each of the pixel regions of FIG. 4. For example, just one of the photodiode 120 may be formed in each of the pixel regions. In one embodiment, the pixels formed in four adjacent pixel regions may share the above-described logic transistors RX, SFX, and SX. In this case, the pixel group PXLG of FIG. 3A may be formed on and in the four adjacent pixel regions. Hereinafter, for convenience of explanation, the pixel region including the pair of sub-pixel regions will be described as an example.

The first shallow element isolation pattern STI1 may be provided in the first substrate 110 to define active regions. The first shallow element isolation pattern STI1 may be adjacent to the first surface 111 of the first substrate 110. The first shallow element isolation pattern STI1 may be provided between the active regions to electrically isolate the active regions from each other. In one embodiment, the first shallow element isolation pattern STI1 may define at least one active region in each of the sub-pixel regions. When the pixel region does not include the sub-pixel regions, the first shallow element isolation pattern STI1 may define at least one active region in each of the pixel regions.

In one embodiment, the first deep element isolation pattern DTI1 may partially overlap the first shallow element isolation pattern STI1. For example, the first deep element isolation pattern DTI1 may pass through a portion of the first shallow element isolation pattern STI1. The overlapping portion of the first deep element isolation pattern DTI1 and the first shallow element isolation pattern STI1 may correspond to a portion of the first shallow element isolation pattern STI1 or a portion of the first deep element isolation pattern DTI1.

The transfer gate TG may be disposed on the first surface 111 of the first substrate 110. The transfer gate TG may be disposed on the corresponding active region of each of the sub-pixel regions (hereinafter, referred to as a first active region). The first gate insulating film 130 may be disposed between the transfer gate TG and the first active region.

The floating diffusion region FD may be provided in the first active region at one side of the transfer gate TG. In one embodiment, the floating diffusion region FD may be a region doped with impurities having the second conductivity type.

In one embodiment, a gate spacer (not shown) may be provided on side surfaces of the transfer gate TG. The gate spacer may include an insulating material different from that of the first shallow element isolation pattern STI1. For example, when the first shallow element isolation pattern STI1 includes a silicon oxide, the gate spacer may include a silicon nitride and/or a silicon oxynitride.

In one embodiment, a capping liner film (not shown) may be disposed on the first surface 111 of the first substrate 110 to conformally cover the first surface 111, the first gate insulating film 130, the gate spacer, and the transfer gate TG.

The light transmitting film 150 (also referred to as a light transmitting layer 150) may be provided on the second surface 113 of the first substrate 110. The light transmitting film 150 may cover the second surface 113 of the first substrate 110 and top surfaces of the first and second deep element isolation patterns DTI1 and DTI2. The light transmitting film 150 may include a transparent insulating material. For example, the light transmitting film 150 may allow over 80%, over 90%, or over 95% of the incident light to transmit through.

In one embodiment, the light transmitting film 150 may perform a function of a film that prevents reflection of light (e.g., by including an anti-reflection film 151) and/or a function of a film having a fixed charge. For example, when the light transmitting film 150 is used as the film that prevents reflection of light, the light transmitting film 150 may prevent the reflection of the light so that light incident on the second surface 113 of the first substrate 110 may smoothly reach the photodiode 120, thereby improving the efficiency of the disclosed photoelectric conversion structure 100 in capturing and converting the light. In addition, for example, when the light transmitting film 150 is used as the film having the fixed charge, the light transmitting film 150 may have a negative fixed charge. In addition, for example, the light transmitting film 150 may include both the film having the fixed charge and the film that prevents the reflection of the light, e.g. stacked in sequence.

In one embodiment, the light transmitting film 150 may have a single-layer or multi-layer structure. For example, the light transmitting film 150 may include at least one of an anti-reflection film 151, a surface insulating film 153, or a capping film 155. However, the structure of the light transmitting film 150 is not limited thereto, and in some embodiments, the light transmitting film 150 may also include other layers in addition to the anti-reflection film 151, the surface insulating film 153, and the capping film 155 that are disclosed.

Referring to FIG. 5, the light transmitting film 150 according to one embodiment may include the anti-reflection film 151, the surface insulating film 153, and the capping film 155. A portion of the anti-reflection film 151 may have an opening such as a recess or a hole passing therethrough to define an opening region, which may be a recess region RR, and accordingly, the anti-reflection film 151 may include the recess region RR. Though shown as a hole passing entirely therethrough, the opening region labeled as recess region RR in the figures may be a recess, which does not pass entirely through the anti-reflection film 151, and a recess region RR is described as one example in the embodiments discussed herein. A plurality of holes, or plurality of recesses, may form an opening pattern, for example, including a plurality of openings (e.g., plurality of recesses or plurality of holes).

The anti-reflection film 151 (also referred to as an anti-reflection portion 151) may be disposed on the second surface 113 of the first substrate 110, and the surface insulating film 153 may be disposed between the anti-reflection film 151 and the second surface 113 of the first substrate 110. The capping film 155 may cover a top surface of the anti-reflection film 151 and a top surface of the light shielding pattern 160. In one embodiment, the anti-reflection film 151 may prevent the reflection of the light, thereby improving efficiency in capturing and converting the light. The anti-reflection film 151 may reduce reflection (for example, by having a tuned index of refraction, a tuned thickness, or a textured surface), and/or anti-reflection film 151 may include one or more materials with a low reflectance. In one embodiment, the anti-reflection film 151 may include an oxide or nitride containing at least one of silicon or hafnium. For example, the anti-reflection film 151 may include at least one of a silicon oxide film, a silicon nitride film, a silicon oxynitride film, a hafnium oxide film, or a hafnium nitride film. In one embodiment, the light shielding pattern 160 may be provided in the anti-reflection film 151.

The light shielding pattern 160 (also referred to as a light shielding portion 160) may be formed in the light transmitting film 150. According to one embodiment, the light shielding pattern 160 may fill the recess region RR of the anti-reflection film 151. In one embodiment, the light shielding pattern 160 may have at least one of a function of absorbing the light, a function of reflecting the light, or a function of blocking the light. In one embodiment, the light shielding pattern 160 may be disposed on a specific pixel region among the pixel regions. For example, the light shielding pattern 160 may be selectively disposed on a pixel region including an autofocusing pixel (hereinafter, referred to as an autofocusing pixel region). For example, the light shielding pattern 160 may cover at least a portion of one of the pair of sub-pixel regions of the autofocusing pixel region. For example, the light shielding pattern 160 may vertically overlap at least a portion of one of the pair of sub-pixel regions of the autofocusing pixel region.

The light shielding pattern 160 may be configured to reduce the amount of light (e.g., by absorbing, reflecting, and/or blocking the light). In various examples, the light shielding pattern 160 may absorb, reflect, and/or block over 50%, over 80%, over 90%, or over 95% of incident light. In one embodiment, the light shielding pattern 160 may include a metal-containing material, a metal nitride, a low refractive material, or an organic material. For example, the light shielding pattern 160 may include at least one of aluminum, titanium, a titanium nitride, tungsten, tantalum, a tantalum nitride, an aluminum oxide, a tantalum oxide, copper, molybdenum, nickel, a red organic material, a green organic material, a blue organic material, a cyan organic material, a magenta organic material, a yellow organic material, a black organic material, or a gray organic material.

In one embodiment, when the light shielding pattern 160 includes an organic material, the light shield pattern 160 may be formed of the organic material that absorbs light passing through the color filter CF. For example, when the color filter CF allows light of a red wavelength to pass through, the light shielding pattern 160 may include at least one of a green organic material, a blue organic material, a cyan organic material, a black organic material, or a gray organic material. For example, when the color filter CF allows light of a blue wavelength to pass through, the light shielding pattern 160 may include at least one of a green organic material, a red organic material, a yellow organic material, a black organic material, or a gray organic material. In addition, when the color filter CF allows light of a green wavelength to pass through, the light shielding pattern 160 may include at least one of a blue organic material, a red organic material, a magenta organic material, a black organic material, or a gray organic material.

In one embodiment, as disclosed in FIG. 5, the recess region RR may pass through the anti-reflection film 151, and the light shielding pattern 160 may be in contact with the surface insulating film 153 and the capping film 155. However, the embodiments of the present application are not limited thereto. In one embodiment, the light shielding pattern 160 may be spaced apart from the surface insulating film 153 and in contact with the capping film 155. In one embodiment, the light shielding pattern 160 may be in contact with the surface insulating film 153 and spaced apart from the capping film 155. In one embodiment, the light shielding pattern 160 may be spaced apart from both the surface insulating film 153 and the capping film 155.

In one embodiment, the surface insulating film 153 may have at least one of the function of a film that prevents reflection of light, the function of a film having a negative fixed charge, or the function of a film that prevents etching. In one embodiment, the surface insulating film 153 may include a metal oxide or a metal fluoride containing at least one of aluminum, hafnium, zirconium, lanthanum, titanium, tantalum, or yttrium. For example, the surface insulating film 153 may include at least one of an aluminum oxide film, a hafnium oxide film, a zirconium oxide film, a lanthanum oxide film, a hafnium silicon oxide film, a hafnium aluminum oxide film, a titanium oxide film, or a tantalum oxide film.

As described above, the capping film 155 may be provided on the anti-reflection film 151 to cover the anti-reflection film 151 and the light shielding pattern 160. For example, the surface insulating film 153, the anti-reflection film 151, and the light shielding pattern 160 may be disposed between the second surface 113 of the first substrate 110 and the capping film 155. In one embodiment, the capping film 155 may have at least one of the function of a film that prevents reflection of light or the function of a film that prevents etching. For example, the capping film 155 may include at least one of a silicon oxide film, a silicon oxynitride film, an aluminum oxide film, a hafnium oxide film, a zirconium oxide film, a lanthanum oxide film, a hafnium silicon oxide film, a hafnium aluminum oxide film, a titanium oxide film, or a tantalum oxide film.

The grid 140 may be provided on the second surface 113 of the first substrate 110 with the light transmitting film 150 therebetween. For example, the grid 140 may be provided on the light transmitting film 150. The grid 140 may define openings. A color filter array including the color filters CF arranged two-dimensionally may be provided on the second surface 113 of the first substrate 110. The color filter array may be provided on the light transmitting film 150, and each of the color filters CF may fill the corresponding opening(s) among the openings of the grid 140. A lens array including the microlenses ML arranged two-dimensionally may be provided on the second surface 113 of the first substrate 110 with the color filter array therebetween. For example, the color filter array may be disposed between the lens array and the light transmitting film 150.

In one embodiment, each of the color filters CF may cover the corresponding pixel regions among the pixel regions. For example, each of the color filters CF may be disposed above four pixel regions arranged in a 2×2 matrix form from the planar perspective. In this example, each of the color filters CF may cover a pair of pixel region groups adjacent to each other. However, the embodiments of the present application are not limited thereto. For example, each of the color filters CF may be disposed above nine pixel regions arranged in a 3×3 matrix form or disposed above sixteen pixel regions arranged in a 4×4 matrix form from the planar perspective.

In one embodiment, the color filters CF may include a first color filter having a first color, a second color filter having a second color, and a third color filter having a third color. For example, each of the color filters CF may have any one among red, green, or blue colors. Alternatively, each of the color filters CF may have any one among cyan, magenta, or yellow colors. The color filters CF may also have other colors in addition to the previously disclosed red, green, blue, cyan, magenta, or yellow colors.

The grid 140 may guide incident light into the photodiode 120. The grid 140 may have a single-layer structure or a multi-layer structure. The grid 140 may include a metal-containing material (e.g., titanium, tungsten, aluminum, tantalum, etc.), a metal nitride (e.g., a titanium nitride, a tantalum nitride, etc.), and/or a low refractive material. The low refractive material may refer to a low refractive index material with a refractive index lower than that of silicon Si. In one embodiment, the low refractive material may include a metal oxide, or a polymer and silica nanoparticles in the polymer. For example, the low refractive material may include at least one of a silicon oxide, an aluminum oxide, a tantalum oxide, or a silicon hydrogen oxynitride. In one embodiment, the low refractive material may have insulating properties.

In one embodiment, the grid 140 may vertically overlap at least the first deep element isolation pattern DTI1. In one embodiment, although not shown, the grid 140 may also vertically overlap the second deep element isolation pattern DTI2. However, the embodiments of the present application are not limited thereto. In one embodiment, when the grid 140 is shifted laterally, at least a portion of the grid 140 may not vertically overlap the first and second deep element isolation patterns DTI1 and DTI2. For example, the grid 140 may have a structure offset laterally from the first and second deep element isolation patterns DTI1 and DTI2. The offset structure may be intentionally selected to optimize an optical path considering a margin of a manufacturing process and/or a traveling angle of the incident light, etc.

The microlens ML may be disposed on the light transmitting film 150 with the color filter CF therebetween. At least a portion of the microlens ML may vertically overlap the photodiode 120. The microlens ML may concentrate light incident toward the first substrate 110. In one embodiment, the microlens ML may include an organic material such as a polymer. For example, the microlens ML may include a light-transmitting resin, a photoresist material, or a thermosetting resin.

In one embodiment, the microlens ML may include a lens pattern and a planarized portion. The planarized portion may be provided on the color filter CF, and the lens pattern may be provided on the planarized portion. The lens pattern may include the same material as the planarized portion. The lens pattern and the planarized portion may configure a single body without a boundary surface therebetween. In one embodiment, the planarized portion may be omitted, and the lens pattern may be directly disposed on the color filter CF.

In one embodiment, the microlenses ML may cover the pixel regions, respectively. For example, each of the microlenses ML may vertically overlap a corresponding one among the pixel regions. Therefore, each of the microlenses ML may cover the pair of sub-pixel regions included in the corresponding pixel region. Each of the microlenses ML may vertically overlap the pair of photodiodes 120 formed in the pair of sub-pixel regions. In one embodiment, each of the microlenses ML in the lens array may vertically overlap a corresponding one among the pixel regions. Each of the microlenses ML may be provided to concentrate the incident light and may include a spherical lens, an aspherical lens, or a combination thereof. For example, each of the microlenses ML may have a convex shape from a cross-sectional perspective.

As described above, the pair of sub-pixels may be formed in and on a pair of sub-pixel regions of the pixel region covered by each of the microlenses ML. For example, the pair of sub-pixels may be covered by the same color filter CF. In one embodiment, the pair of sub-pixels may perform not only a photoelectric conversion function converting optical signals into electrical signals, but also an autofocusing function. For example, the pair of sub-pixels may detect a phase difference of light incident through the corresponding microlens ML thereof, and the autofocusing function may be performed using the detected phase difference data.

According to the image sensor in the above-described embodiments, the recess region RR may be formed in the light transmitting film 150 or the anti-reflection film 151, and the light shielding pattern 160 may fill the recess region RR. In this case, the light shielding pattern 160 may be selectively disposed on the autofocusing pixel region among the pixel regions to cover at least a portion of one of the pair of sub-pixel regions in the autofocusing pixel region. Therefore, the light shielding pattern 160 that absorbs or blocks light can be selectively provided in the autofocusing pixel (AF pixel), and a configuration that absorbs or blocks light can be minimized in non-autofocusing pixels (non-AF pixels). For example, the amount of light incident on the autofocusing pixel may be partially limited to facilitate detecting the phase difference of the incident light for autofocusing. At the same time, the light shielding pattern 160 may not be provided, and/or the light transmitting film 150 or anti-reflection film 151 may be provided, over the non-autofocusing (e.g., standard) pixels. Thus, it is possible to increase the amount of light incident on the non-autofocusing pixels and to minimize the amount of loss of light incident on the non-autofocusing pixel. As a result, it is possible to increase the quantum efficiency QE of the image sensor.

In some examples, extraneous light may interfere with the functionality of the autofocusing pixel (AF pixel), whereas additional incident light may improve the efficiency and/or performance of non-autofocusing pixels (non-AF pixels). For example, too much incident light may make it difficult for the AF pixel to accurately detect a phase difference of the light. Accordingly, as described above, light shielding pattern 160 can be selectively provided in the AF pixel, and the configuration that absorbs or blocks light can be minimized in non-AF pixels.

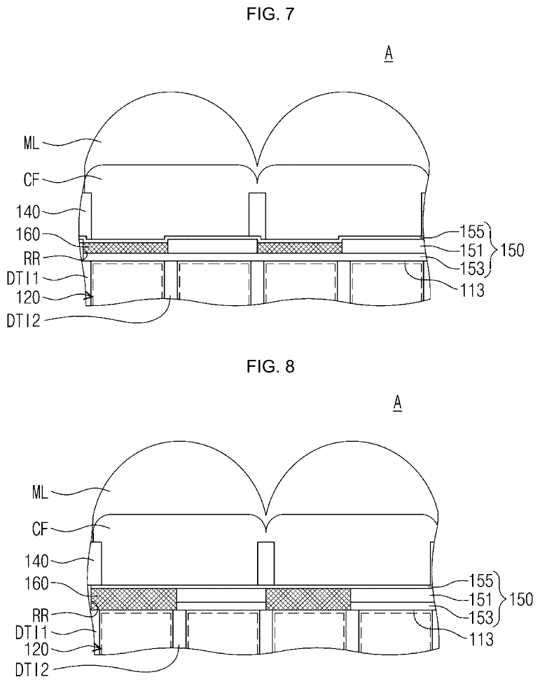

FIGS. 6 and 7 show image sensors according to some embodiments of the present application, which are enlarged cross-sectional views corresponding to portion ‘A’ of FIG. 4. Hereinafter, for convenience of explanation, differences from the above-described embodiments will be mainly described.

Referring to FIGS. 6 and 7, the light shielding pattern 160 and the anti-reflection film 151 may be disposed on the surface insulating film 153, and the capping film 155 may be disposed on the anti-reflection film 151 and the light shielding pattern 160. In one embodiment, a thickness of the light shielding pattern 160 may differ from a thickness of the anti-reflection film 151. The thickness of the light shielding pattern 160 and the thicknesses of the anti-reflection film 151 according to one embodiment may be adjusted by changing a selectivity during a process of planarizing the light shielding pattern 160 and the anti-reflection film 151, and the thickness of the light shielding pattern 160 and/or the thicknesses of the anti-reflection film 151 may be appropriately adjusted as needed, and therefore are not limited.

In the embodiment of FIG. 6, the thickness of the light shielding pattern 160 may be larger than the thickness of the anti-reflection film 151. For example, the thickness of the anti-reflection film 151 may be smaller than the thickness of the light shielding pattern 160. In this case, the capping film 155 may be formed after the formation of the light shielding pattern 160. Accordingly, a portion of the capping film 155 may have a step, and a level (e.g., a height in the vertical dimension) of a top surface of the capping film 155 on the light shielding pattern 160 may be higher than a level of the top surface of the capping film 155 on the anti-reflection film 151. Accordingly, a portion of the capping film 155 may have the step, as shown in FIG. 6, but the present disclosure is not limited thereto.

In the embodiment of FIG. 7, the thickness of the light shielding pattern 160 may be smaller than the thickness of the anti-reflection film 151. For example, the thickness of the anti-reflection film 151 may be larger than the thickness of the light shielding pattern 160. In this case, the capping film 155 may be formed after the formation of the light shielding pattern 160. Accordingly, a portion of the capping film 155 may have a step, and a level of a top surface of the capping film 155 on the light shielding pattern 160 may be lower than a level of the top surface of the capping film 155 on the anti-reflection film 151. Accordingly, a portion of the capping film 155 may have the step, as shown in FIG. 7, but the present disclosure is not limited thereto.

FIGS. 8 to 10 show image sensors according to some embodiments of the present application, which are enlarged cross-sectional views corresponding to portion ‘A’ of FIG. 4.

Referring to FIG. 8, the recess region RR may extend to the inside of the surface insulating film 153. For example, the recess region RR may pass through at least portions of the anti-reflection film 151 and the surface insulating film 153, and the anti-reflection film 151 and the surface insulating film 153 may include the recess region RR. Accordingly, the light shielding pattern 160 may be provided within the anti-reflection film 151 and the surface insulating film 153. In one embodiment, the recess region RR may also pass through the surface insulating film 153. Accordingly, a lower portion of the light shielding pattern 160 filling the recess region RR may protrude lower than a bottom surface of the anti-reflection film 151, the surface insulating film 153 may surround a side surface of the lower portion of the light shielding pattern 160, and a bottom surface of the light shielding pattern 160 may be substantially coplanar with a bottom surface of the surface insulating film 153.

The light shielding pattern 160 in FIG. 8 is shown as being in contact with the second surface 113 of the first substrate 110 and the capping film 155, but is not limited thereto. In some embodiments, the light shielding pattern 160 may be in contact with one of the second surface 113 of the first substrate 110 and the capping film 155 and may be spaced apart from the other one thereof. In one embodiment, the light shielding pattern 160 may be spaced apart from the second surface 113 of the first substrate 110 and the capping film 155.

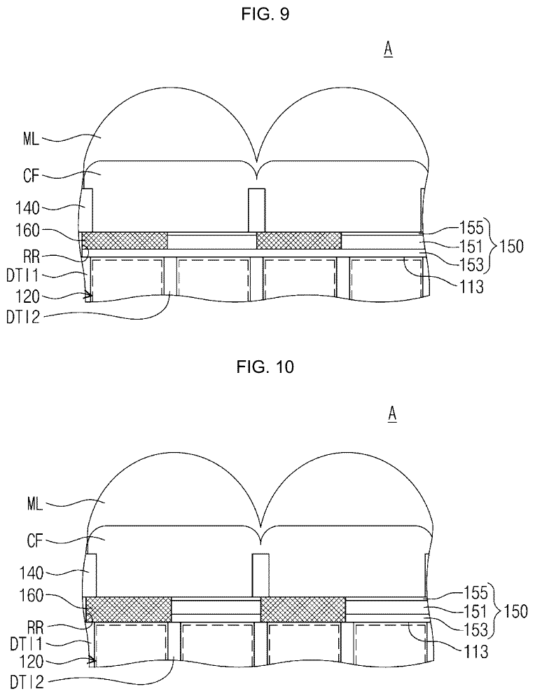

Referring to FIG. 9, the recess region RR may extend to the inside of the capping film 155. For example, the recess region RR may pass through the anti-reflection film 151 and the capping film 155, and the light shielding pattern 160 may fill the recess region RR. Accordingly, the light shielding pattern 160 may be provided within the anti-reflection film 151 and the capping film 155. An upper portion of the light shielding pattern 160 may protrude higher than a top surface of the anti-reflection film 151, the capping film 155 may surround a side surface of the upper portion of the light shielding pattern 160, and a top surface of the light shielding pattern 160 may be substantially coplanar with a top surface of the capping film 155.

The light shielding pattern 160 in FIG. 9 is shown as being in contact with the grid 140, the color filter CF, and the surface insulating film 153, but is not limited thereto. In some embodiments, the light shielding pattern 160 may be in contact with one of the color filter CF and the surface insulating film 153, and may be spaced apart from the other one thereof. In one embodiment, the light shielding pattern 160 may be spaced apart from the grid 140, the color filter CF, and the surface insulating film 153.

Referring to FIG. 10, the recess region RR may extend to the insides of the surface insulating film 153 and the capping film 155. For example, the recess region RR may pass through at least portions of the capping film 155, the anti-reflection film 151, and the surface insulating film 153. Accordingly, the light shielding pattern 160 may be provided within the anti-reflection film 151, the surface insulating film 153, and the capping film 155. In this case, the lower portion of the light shielding pattern 160 may protrude lower than the bottom surface of the anti-reflection film 151 like the lower portion of the light shielding pattern 160 in FIG. 8, and the upper portion of the light shielding pattern 160 may protrude higher than the top surface of the anti-reflection film 151 like the upper portion of the light shielding pattern 160 in FIG. 9.

The light shielding pattern 160 in FIG. 10 is shown as being in contact with the grid 140, the color filter CF, and the second surface 113 of the first substrate 110, but is not limited thereto. In some embodiments, the light shielding pattern 160 may be in contact with one of the color filter CF and the second surface 113, and spaced apart from the other one thereof. In one embodiment, the light shielding pattern 160 may be spaced apart from the grid 140, the color filter CF, and the second surface 113.

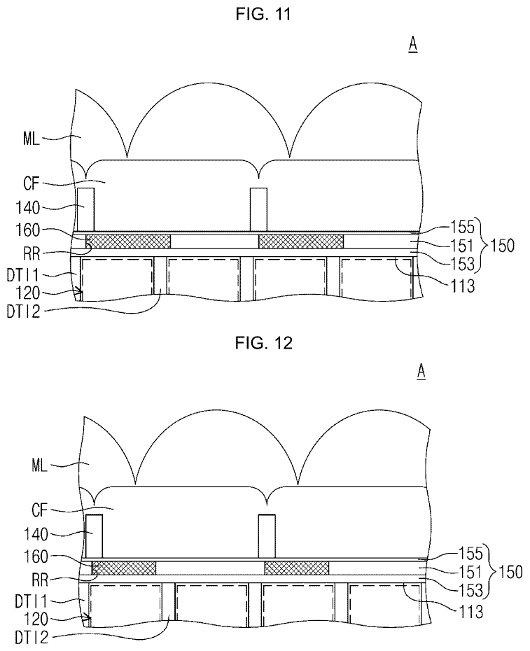

FIGS. 11 to 13 show image sensors according to some embodiments of the present application, which are enlarged cross-sectional views corresponding to portion ‘A’ of FIG. 4.

Referring to FIGS. 11 to 13, a location and/or width of the light shielding pattern 160 may be appropriately changed as needed. As described above, when the grid 140 is laterally shifted along a path of the incident light, the location of the light shielding pattern 160 may be changed. For example, a horizontal location of the light shielding pattern 160 may be changed in proportion to a distance by which the grid 140 is shifted laterally from the first deep trench isolation pattern DTI1.

The light shielding pattern 160 of FIG. 5 may cover one of the pair of sub-pixel regions and the first and second deep trench isolation patterns DTI1 and DTI2 at both sides of one of the sub-pixel region, whereas the shifted light shielding pattern 160 of FIG. 11 may not vertically overlap the first deep trench isolation pattern DTI1 and may overlap vertically one of the pair of sub-pixel regions and a portion of the other of the pair of sub-pixel regions.

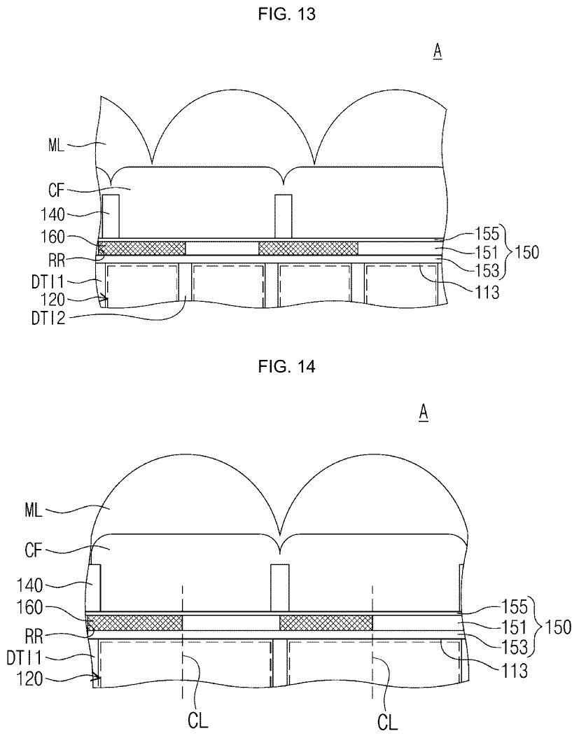

The shifted light shielding pattern 160 of FIG. 12 may cover one of the pair of sub-pixel regions, but may not cover the other of the pair of sub-pixel regions. A horizontal width of the light shielding pattern 160 of FIG. 12 may be narrower than a width of the light shielding pattern 160 of FIG. 11. The shifted light shielding pattern 160 of FIG. 13 may cover at least a portion of the first deep trench isolation pattern DTI1 and portions of one of the pair of sub-pixel regions and the other one of the pair of sub-pixel regions. A width of the light shielding pattern 160 of FIG. 13 may be wider than a width of the light shielding pattern 160 of FIG. 11. As a result, the horizontal location of the light shielding pattern 160 may be changed according to the shift in the grid 140, and the width of the light shielding pattern 160 may be appropriately adjusted as needed.

FIG. 14 shows an image sensor according to one embodiment of the present application, which is an enlarged cross-sectional view corresponding to portion ‘A’ of FIG. 4.

FIG. 14 shows neighboring autofocusing pixel regions. Referring to FIG. 14, in the present embodiment, one of the photodiode 120 may be provided in each of the pixel regions. For example, unlike the above-described embodiments, the pixel region may not include the pair of sub-pixel regions and the second deep element isolation pattern therebetween. Here, the light shielding pattern 160 may cover a portion of at least one of the pixel regions. For example, the light shielding pattern 160 may cover a portion of the autofocusing pixel region. As described above, the one photodiode 120 may be provided in the autofocusing pixel region, and the light shielding pattern 160 may cover a portion of the photodiode 120 in the autofocusing pixel region. The light shielding pattern 160 may be one of the light shielding patterns 160 of FIGS. 5 to 13.

The autofocusing pixel region may be divided into a left portion and a right portion with respect to a virtual center line CL passing through the center of the photodiode 120 and perpendicular to the second surface 113. In one embodiment, as shown in FIG. 14, the light shielding pattern 160 may cover the left portion of the autofocusing pixel region. However, the embodiments of the present application are not limited thereto. In one embodiment, the light shielding pattern 160 may also cover the right portion of the autofocusing pixel region. In some embodiments, the pixel regions may include a plurality of autofocusing pixel regions, and one light shielding pattern 160 may cover a left portion of at least one of the autofocusing pixel regions, and the other light shielding pattern 160 may cover a right portion of at least the other of the autofocusing pixel regions.

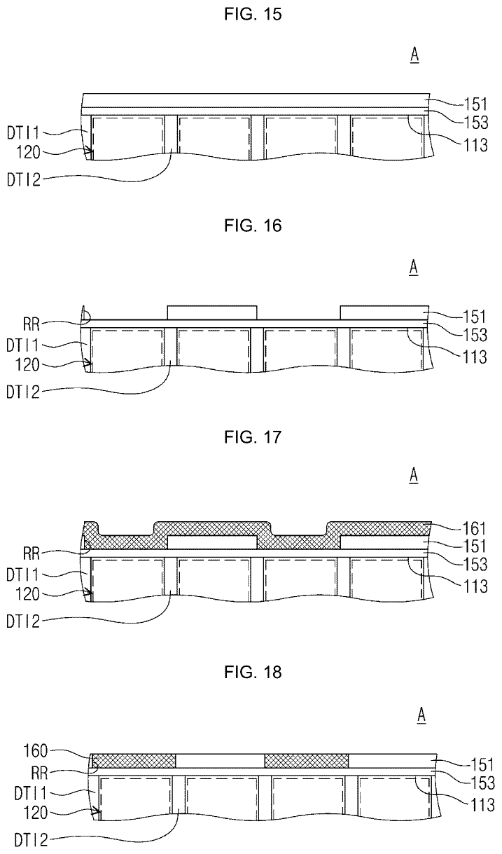

FIGS. 15 to 19 are cross-sectional views showing a method of manufacturing the image sensor according to one embodiment of the present application. FIGS. 15 to 19 are enlarged cross-sectional views corresponding to portion ‘A’ of FIG. 4.

Referring to FIG. 15, the first substrate 110 having the first and second surfaces 111 and 113 may be provided, and the first and second deep element isolation patterns DTI1 and DTI2 may be formed in the first substrate 110. The first deep element isolation pattern DTI1 may define the pixel region, and the second deep element isolation pattern DTI2 may be formed between the pair of sub-pixel regions of the pixel region. The photodiodes 120 may be formed in each of the sub-pixel regions using an ion implantation process. In some embodiments, the photodiodes 120 may be formed before or after the formation of the first and second deep element isolation patterns DTI1 and DTI2. Thereafter, various components (e.g., the transfer gate TG, the floating diffusion region FD, and interlayer insulating films, wirings) may be formed on the second surface 113 of the first substrate 110. Thereafter, the first substrate 110 may be coupled to another substrate, and then the second surface 113 of the first substrate 110 may be planarized. In one embodiment, the surface insulating film 153 may be formed on the planarized second surface 113 of the first substrate 110, and the anti-reflection film 151 may be formed on the surface insulating film 153.

Referring to FIG. 16, a mask pattern (not shown) may be formed on the anti-reflection film 151. The mask pattern may have an opening defining the recess region RR. The opening may expose a portion of the anti-reflection film 151. The anti-reflection film 151 may be etched using the mask pattern as an etching mask to form the recess region RR in the anti-reflection film 151.

In one embodiment, the etching process for forming the recess region RR may be performed until the surface insulating film 153 is exposed. In this case, the exposed surface of the surface insulating film 153 may correspond to a bottom surface of the recess region RR. In one embodiment, a level (e.g., a height in the vertical dimension) of the bottom surface of the recess region RR may be substantially the same as a level of a top surface of the surface insulating film 153 or the bottom surface of the anti-reflection film 151. However, the embodiments of the present application are not limited thereto. In some embodiments, when the etching process is stopped before the surface insulating film 153 is exposed or includes over-etching, the level of the bottom surface of the recess region RR may differ from the level of the top surface of the surface insulating film 153 or the bottom surface of the anti-reflection film 151.

The mask pattern may be removed after the recess region RR is formed. As previously disclosed, the level of the bottom surface of the recess region RR may be substantially the same as the level of the top surface of the surface insulating film 153 or the bottom surface of the anti-reflection film 151.

Referring to FIG. 17, the light shielding film 161 may be formed on the anti-reflection film 151 having the recess region RR. The light shielding film 161 may fill the recess region RR. For example, the light shielding film 161 may be formed using a deposition process. In one embodiment, the light shielding film 161 may include a metal-containing material, a metal nitride, a low refractive material, or an organic material. For example, the light shielding film 161 may be made of at least one of aluminum, titanium, a titanium nitride, tungsten, tantalum, a tantalum nitride, an aluminum oxide, a tantalum oxide, copper, molybdenum, nickel, a red organic material, a green organic material, a blue organic material, a cyan organic material, a magenta organic material, a yellow organic material, a black organic material, and a gray organic material.

Referring to FIG. 18, a planarization process may be performed on the light shielding film 161 to form the light shielding pattern 160.

In one embodiment, the top surface of the light shielding pattern 160 may be substantially coplanar with the top surface of the anti-reflection film 151. In this case, the planarization process may be performed until the anti-reflection film 151 is exposed. Accordingly, the image sensor shown in FIG. 5 may be manufactured.

Alternatively or additionally, the process may be modified suitably to manufacture the image sensor shown in any of the embodiments of FIGS. 6-14. For example, in one embodiment, a thickness of the light shielding pattern 160 may be formed to be larger than a thickness of the anti-reflection film 151. In this case, the planarization process may be performed until the anti-reflection film 151 is exposed, and an additional etching process may be performed on the exposed anti-reflection film 151. Accordingly, the top surface of the etched anti-reflection film 151 may be lower than the top surface of the light shielding pattern 160, and the image sensor shown in FIG. 6 may be manufactured.

In one embodiment, the thickness of the light shielding pattern 160 may be formed to be smaller than the thickness of the anti-reflection film 151. In this case, the planarization process may include a process of over-etching the light shielding film 161 after the anti-reflection film 151 is exposed. Accordingly, the top surface of the light shielding pattern 160 may be lower than the top surface of the anti-reflection film 151, and the image sensor shown in FIG. 7 may be manufactured.

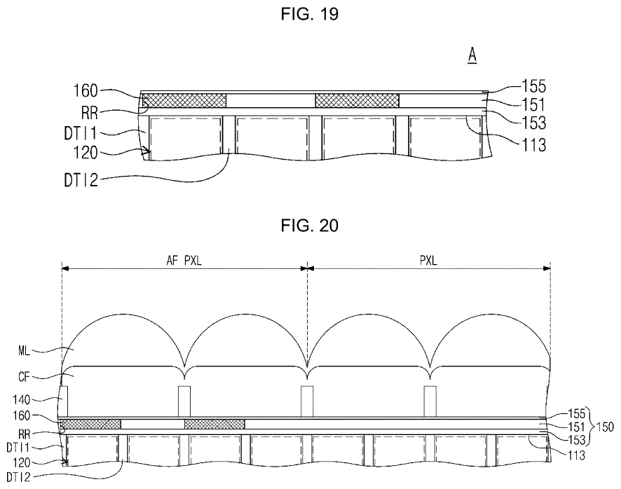

Referring to FIG. 19, the capping film 155 may be formed on the anti-reflection film 151 and the light shielding pattern 160. Thereafter, the grid 140, the color filter CF, and the microlens ML of FIG. 5 may be formed on the capping film 155.

In one embodiment, the image sensors of FIGS. 8 to 10 may be manufactured by changing a patterning process (e.g., a process of forming the mask pattern and an etching process using the mask pattern as an etching mask) for forming the recess region RR in various ways. In one embodiment, during the etching process described with reference to FIG. 16, the anti-reflection film 151 and the surface insulating film 153 may be etched. Accordingly, the image sensor of FIG. 8 may be manufactured. In one embodiment, the patterning process for forming the recess region RR may be performed after the capping film 155 is formed, and the capping film 155 and the anti-reflection film 151 may be etched by the etching process of the patterning process. Accordingly, the image sensor of FIG. 9 may be manufactured. In one embodiment, the patterning process may be performed after the capping film 155 is formed, and the capping film 155, the anti-reflection film 151, and the surface insulating film 153 may be etched by the etching process of the patterning process. Accordingly, the image sensor of FIG. 10 may be manufactured.

FIG. 20 shows an image sensor according to one embodiment of the present application, which is an enlarged cross-sectional view corresponding to portion ‘A’ of FIG. 4.

Referring to FIG. 20, the light shielding pattern 160 may be formed on an autofocusing pixel AF PXL, but may not be formed on a general pixel PXL. The light shielding pattern 160 may absorb or block some of light incident through the microlens ML to reduce the amount of light incident on some regions. As discussed above, extraneous light may interfere with the functionality of an autofocusing pixel, for example detecting a phase difference of the light, whereas additional incident light may improve the efficiency and/or performance of non-autofocusing pixels. Accordingly, the autofocusing pixel AF PXL may detect a phase difference of the incident light, and an autofocusing function may be performed using the detected phase difference data. As a result, since the light shielding pattern 160 is not formed on the general pixel PXL, it is possible to minimize the amount of loss of light incident on the general pixel PXL. Accordingly, it is possible to increase the quantum efficiency (QE) of the image sensor.

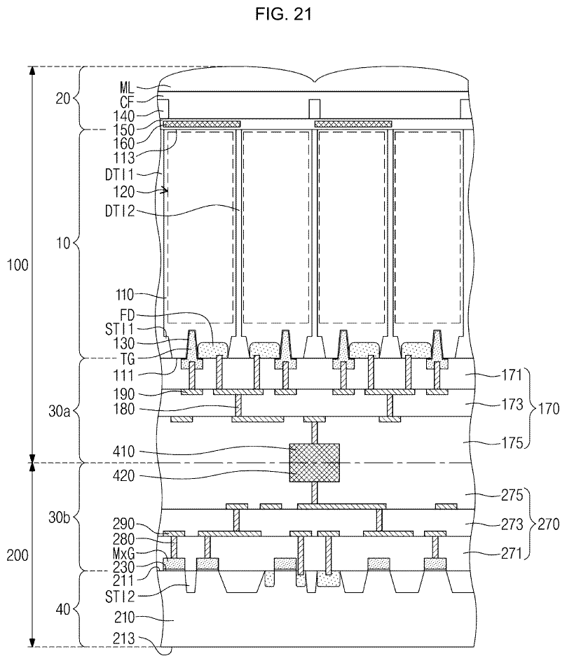

FIG. 21 is a cross-sectional view of an image sensor according to one embodiment of the present application.

Referring to FIG. 21, the image sensor according to one embodiment may include first and second structures 100 and 200. The first structure 100 may be stacked on the second structure 200. Thai is, the image sensor according to one embodiment may have a stacked structure. The first structure 100 may also be referred to herein as a photoelectric conversion structure (e.g., the first structure 100 may be the photoelectric conversion structure 100 of FIG. 4). The second structure 200 may be referred to as a nearby circuit structure, and may include, for example, circuitry to process the pixel data into an image. The first structure 100 and the second structure 200 may be bonded to each other by at least one of various bonding methods and electrically connected to each other by at least one of various connection methods.

The first structure 100 may include a light control layer 20, a photoelectric conversion layer 10, and a first wiring layer 30a. The photoelectric conversion layer 10 may be disposed between the light control layer 20 and the first wiring layer 30a.

The light control layer 20 may include the microlenses ML, the color filter CF, the grid 140, the light transmitting film 150, and the light shielding pattern 160 of FIG. 5. The photoelectric conversion layer 10 may include the first substrate 110, the photodiodes 120, the first deep element isolation pattern DTI1, the second deep element isolation pattern DTI2, the first shallow element isolation pattern STI1, the floating diffusion regions FD, the first gate insulating films 130, and the transfer gates TG of FIG. 4. The first wiring layer 30a may include first interlayer insulating films 170, first contact plugs 180, first wirings 190, and a first bonding pad 410.

The first interlayer insulating films 170 may be provided on the first surface 111 of the first substrate 110. The first interlayer insulating films 170 may cover the first surface 111, the floating diffusion regions FD, and the transfer gates. For example, each of the first interlayer insulating films 170 may include at least one of a silicon oxide, a silicon oxynitride, and a silicon nitride. In one embodiment, the first interlayer insulating films 170 may be sequentially stacked on the first surface 111 of the first substrate 110. The first contact plugs 180 and the first wirings 190 may be provided in the first interlayer insulating films 170.

The first bonding pad 410 may be disposed in a first interlayer insulating film 175 that is a lowermost layer of the first interlayer insulating films 170.

The second structure 200 may include a nearby circuit layer 40 and a second wiring layer 30b.

The nearby circuit layer 40 may include a second substrate 210, a second shallow element isolation pattern STI2, a second gate insulating film 230, and nearby circuit gates MxG, and the second wiring layer 30b may include second interlayer insulating films 270, second contact plugs 280, second wirings 290, and a second bonding pad 420.

The second substrate 210 may have a third surface 211 and a fourth surface 213 opposite to the third surface 211. The third surface 211 may be a front surface of the second substrate 210, and the fourth surface 213 may be a back surface of the second substrate 210. The second shallow element isolation pattern STI2 may be disposed in a shallow trench that is recessed by a specific depth from the third surface 211 of the second substrate 210.

The second shallow element isolation pattern STI2 may define active regions in the second substrate 210. The second shallow element isolation pattern STI2 may be adjacent to the third surface 211 of the second substrate 210.

The nearby circuit gates MxG may be disposed on corresponding active regions of the second substrate 210. In one embodiment, the nearby circuit gates MxG may be disposed on the third surface 211 of the second substrate 210. The second gate insulating film 230 may be disposed between the nearby circuit gates MxG and the corresponding active regions. Nearby circuit source/drain regions may be disposed in corresponding active regions at both sides of each of the nearby circuit gates MxG.

The second interlayer insulating films 270 may be disposed on the third surface 211 of the second substrate 210 to cover the third surface 211, the second gate insulating film 230, and the nearby circuit gates MxG. The second interlayer insulating films 270 may be sequentially stacked on the third surface 211 of the second substrate 210. The second contact plugs 280 and the second wirings 290 may be provided in the second interlayer insulating films 270. The second bonding pad 420 may be disposed in a second interlayer insulating film 275 that is an uppermost layer of the second interlayer insulating films 270.

The first and second bonding pads 410 and 420 may electrically connect the first and second structures 100 and 200. In one embodiment, the first bonding pad 410 and the second bonding pad 420 may be bonded to each other to electrically connect the first structure 100 to the second structure 200. In one embodiment, the first and second bonding pads 410 and 420 may include copper. The first and second bonding pads 410 and 420 may be bonded to each other by a copper-copper bonding technique. The bonded bonding pads 410 and 420 may configure a single body without a boundary surface therebetween. In one embodiment, the first interlayer insulating film 175 that is the lowermost layer may be covalently bonded to the second interlayer insulating films 275 that are the uppermost layer.

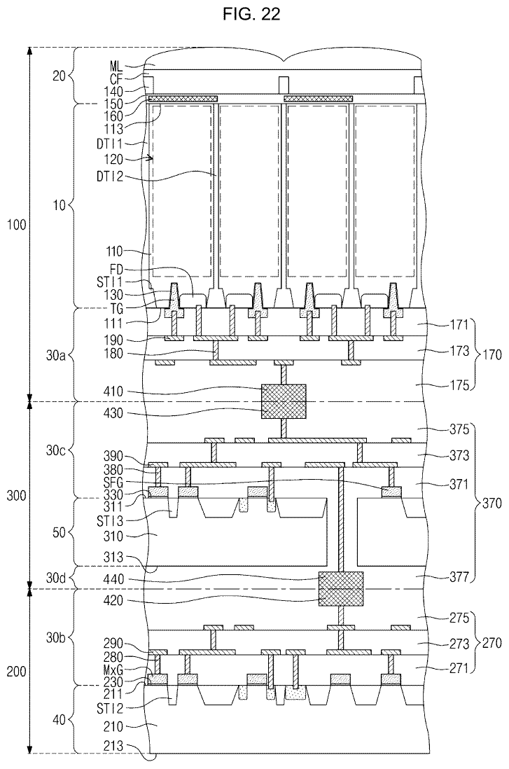

FIG. 22 is a cross-sectional view of an image sensor having multiple structures, according to one embodiment of the present application.

Referring to FIG. 22, the image sensor according to one embodiment may include first to third structures 100, 200, and 300. The first structure 100 may be stacked on the third structure 300, and the third structure 300 may be stacked on the second structure 200. For example, the third structure 300 may be disposed between the first structure 100 and the second structure 200. The third structure 300 may also be referred to as an intermediate structure. The first structure 100 and the third structure 300 may be bonded to each other by at least one of various bonding methods and electrically connected to each other by at least one of various connection methods, and the second structure 200 and the third structure 300 may be bonded to each other by at least one of various bonding methods and electrically connected to each other by at least one of various connection methods.

The third structure 300 may include an intermediate layer 50, a third wiring layer 30c, and a fourth wiring layer 30d. The intermediate layer 50 may be disposed between the third wiring layer 30c and the fourth wiring layer 30d.

The intermediate layer 50 may include a third substrate 310, a third shallow element isolation pattern STI3, a third gate insulating film 330, and gates. The third wiring layer 30c may include at least one of the third interlayer insulating films 370, third contact plugs 380, third wirings 390, and a third bonding pad 430. The fourth wiring layer 30d may include at least the other one of the third interlayer insulating films 370, and a fourth bonding pad 440.

The third substrate 310 may have a fifth surface 311 and a sixth surface 313 opposite to the fifth surface 311. The fifth surface 311 may be a front surface of the third substrate 310, and the sixth surface 313 may be a back surface of the third substrate 310. Conversely, the fifth surface 311 may be the back surface of the third substrate 310, and the sixth surface 313 may be the front surface of the third substrate 310.

The third shallow element isolation pattern STI3 may be disposed in a shallow trench that is recessed by a specific depth from the fifth surface 311 of the third substrate 310. The third shallow element isolation pattern STI3 may define active regions in the third substrate 310. In one embodiment, the third shallow element isolation pattern STI3 may be adjacent to the fifth surface 311 of the third substrate 310.

The gates (e.g., a reset gate, a selection gate, a source follower gate SFG, etc.) may be disposed on corresponding active regions of the third substrate 310. In one embodiment, the reset gate, the selection gate, and the source follower gate SFG may be disposed on the fifth surface 311 of the third substrate 310. The third gate insulating film 330 may be disposed between each of the reset gate, the selection gate, and the source follower gate SFG and the corresponding active region. The source/drain regions may be disposed in the corresponding active regions at both sides of each of the gates.

At least one of the third interlayer insulating films 370 may be disposed on the fifth surface 311 of the third substrate 310 to cover the fifth surface 311, the third gate insulating film 330, the reset gate, the selection gate, and the source follower gate SFG. In one embodiment, a plurality of third interlayer insulating films 370 may be sequentially stacked on the fifth surface 311 of the third substrate 310. At least the other one of the third interlayer insulating films 370 may be disposed on (e.g., beneath) the sixth surface 313 of the third substrate 310. For example, a third interlayer insulating film 377 may be disposed on (e.g., beneath) the sixth surface 313 of the third substrate 310. The third contact plugs 380 and the third wirings 390 may be provided in the third interlayer insulating films 370.

The third bonding pad 430 may be disposed in a third interlayer insulating film 375 that is an uppermost layer of the third interlayer insulating films 370, and the fourth bonding pad 440 may be disposed in the third interlayer insulating film 377 that is a lowermost layer of the third interlayer insulating films 370.

The first to fourth bonding pads 410, 420, 430, and 440 may electrically connect the first to third structures 100, 200, and 300. In one embodiment, the first bonding pad 410 and the third bonding pad 430 may be bonded to each other to electrically connect the first structure 100 to the third structure 300. In one embodiment, the second bonding pad 420 and the fourth bonding pad 440 may be bonded to each other to electrically connect the second structure 200 to the third structure 300.

In one embodiment, the third structure 300 may be bonded differently from that shown in FIG. 22, for example, it may be inverted (e.g., reflected) vertically, inverted (e.g., reflected) both vertically and horizontally, rotated by 180°, etc. For example, the first bonding pad 410 and the fourth bonding pad 440 may be bonded to each other to electrically connect the first structure 100 to the third structure 300. For example, the first bonding pad 410 and the fourth bonding pad 440 may be bonded to each other so as to electrically connect the first structure 100 to the third structure 300.

In one embodiment, the third and fourth bonding pads 430 and 440 may include copper, as do the first and second bonding pads 410 and 420. The pads bonded to each other among the first to fourth bonding pads 410, 420, 430, and 440 may be bonded by the copper-copper bonding technique, for example the pads bonded to each other may configure a single body without a boundary surface therebetween.

In one embodiment, the bonded films among the first to third interlayer insulating films 170, 270, and 370 may be bonded to each other by forming a covalent bond. For example, the first interlayer insulating film 175 that is the lowermost layer of the first interlayer insulating films 170 may be bonded to the third interlayer insulating film 375 that is the uppermost layer of the third interlayer insulating films 370. For example, the second interlayer insulating film 275 that is the uppermost layer of the second interlayer insulating films 270 may be bonded to the third interlayer insulating film 377 that is the lowermost layer of the third interlayer insulating films 370.

In one embodiment, when the third structure 300 is inverted (e.g., reflected) vertically and coupled (not shown, e.g. upside-down inversion, upside-down left-right inversion, 180°rotation, etc.), the first interlayer insulating film 175 that is the lowermost layer of the first interlayer insulating films 170 may be bonded to the third interlayer insulating film 377 that is the uppermost layer of the third interlayer insulating films 370, and the second interlayer insulating film 275 that is the uppermost layer of the second interlayer insulating films 270 may be bonded to the third interlayer insulating film 375 that is the lowermost layer of the third interlayer insulating films 370.

According to one embodiment of the present application, the quantum efficiency (QE) can be increased by selectively forming a light shielding pattern.

Although the present application has been described above with reference to the exemplary embodiments of the present application, those skilled in the art or those having ordinary skill in the art will be able to understand that the present application may be modified and changed in various ways without departing from the spirit and technical scope of the present application as described in the appended claims. For example, it is understood that the above-described embodiments may be combined in various forms to the extent that they are compatible with each other.

Therefore, the technical scope of the present application should not be limited to the contents described in the detailed descriptions of the specification, but should be determined by the patent claims.

What is claimed is:

1. An image sensor comprising:
a substrate having a first surface and a second surface opposite to the first surface and including pixel regions spaced apart from each other;
a light transmitting layer covering the second surface, and including an anti-reflection portion having an opening;
a light shielding portion provided in the light transmitting layer, filling the opening, and covering a portion of a first pixel region of the pixel regions;
a grid disposed on the light transmitting layer;
color filters filling openings of the grid; and
microlenses disposed on the color filters.

2. The image sensor of claim 1, wherein
the first pixel region covered by the light shielding portion includes at least one autofocusing pixel.

3. The image sensor of claim 1, wherein:
each of the pixel regions includes
a pair of sub-pixel regions spaced apart from each other and
a pair of photodiodes provided in the pair of sub-pixel regions, respectively; and
the light shielding portion covers one of the pair of sub-pixel regions.

4. The image sensor of claim 1, further comprising
a single photodiode provided in each of the pixel regions,
wherein
the light shielding portion covers a portion of the single photodiode of the first pixel region.

5. The image sensor of claim 1, wherein
the light transmitting layer further includes a surface insulating film disposed between the second surface and the light shielding portion and between the second surface and the anti-reflection portion.

6. The image sensor of claim 5, wherein
the light transmitting layer further includes a capping film covering the light shielding portion and the anti-reflection portion.

7. The image sensor of claim 1, wherein:
the light transmitting layer is above the second surface;
the light shielding portion is provided at the same height as the light transmitting layer;
the light shielding portion is above the portion of the first pixel region;
the grid is above the light transmitting layer; and
the microlenses are above the color filters.

8. The image sensor of claim 7, wherein
the light shielding portion has a lower portion protruding lower than a bottom surface of the anti-reflection portion,
the light transmitting layer further includes a surface insulating film disposed between the anti-reflection portion and the second surface, and
the surface insulating film surrounds at least a side surface of the lower portion of the light shielding portion.

9. The image sensor of claim 7, wherein
the light transmitting layer further includes a capping film provided on the anti-reflection portion,
the light shielding portion has an upper portion protruding higher than a top surface of the anti-reflection portion, and
a side surface of the upper portion of the light shielding portion is surrounded by the capping film.

10. The image sensor of claim 1, wherein
a thickness of the light shielding portion differs from a thickness of the anti-reflection portion.

11. The image sensor of claim 1, wherein the light shielding portion is made of a material that reflects, blocks, and/or absorbs light.

12. The image sensor of claim 11, wherein
the light shielding portion is made of at least one of aluminum, titanium, a titanium nitride, tungsten, tantalum, a tantalum nitride, an aluminum oxide, a tantalum oxide, copper, molybdenum, nickel, a red organic material, a green organic material, a blue organic material, a cyan organic material, a magenta organic material, a yellow organic material, a black organic material, or a gray organic material.

13. The image sensor of claim 1, further comprising:
a transfer gate disposed on the first surface of the substrate and provided on each of the pixel regions; and
a floating diffusion region provided in each of the pixel regions at one side of the transfer gate and adjacent to the first surface.

14. An image sensor comprising:
a substrate having a first surface and a second surface opposite to the first surface;
a first deep element isolation pattern disposed in the substrate to correspond to pixel regions, each of which includes a pair of sub-pixel regions;
a second deep element isolation pattern disposed between a respective pair of sub-pixel regions;
an anti-reflection portion covering the second surface and having an opening;
a light shielding portion filling the opening;
a grid disposed on the anti-reflection portion;
color filters filling openings of the grid; and
microlenses disposed on the color filters,
wherein
at least a first pixel region of the pixel regions is part of an autofocusing pixel, and
the light shielding portion covers at least a portion of one of the pair of sub-pixel regions of the first pixel region.

15. The image sensor of claim 14, further comprising
a surface insulating film disposed between the second surface and the light shielding portion and between the second surface and the anti-reflection portion.

16. The image sensor of claim 14, wherein
a thickness of the light shielding portion differs from a thickness of the anti-reflection portion.

17. The image sensor of claim 14, wherein
the light shielding portion is made of a material that reflects, blocks, and/or absorbs light.

18. A method of manufacturing an image sensor comprising:
forming a surface insulating film on one surface of a substrate;
forming an anti-reflection film on the surface insulating film;
etching the anti-reflection film to form an opening in the anti-reflection film;
forming a light shielding portion in the opening; and
forming a capping film on the light shielding portion and the anti-reflection film.

19. The method of claim 18, wherein
the forming the light shielding portion includes:
forming a light shielding film filling the opening on the anti-reflection film; and
planarizing the light shielding film to form the light shielding portion, and wherein
when the light shielding film is planarized, the light shielding film is over-etched so that a top surface of the light shielding portion is lower than a top surface of the anti-reflection film.

20. The method of claim 18, wherein
the forming the light shielding portion includes:
forming a light shielding film filling the opening on the anti-reflection film;
planarizing the light shielding film until the anti-reflection film is exposed to form the light shielding portion; and
etching the exposed anti-reflection film, wherein
a top surface of the etched anti-reflection film is lower than a top surface of the light shielding portion.
